(19) United States
(12) Patent Application Publication
(10) Pub. No.: US 2022/0099743 A1
(43) Pub. Date: Mar. 31, 2022

(54) Method and Apparatus for Operating a System for Providing Predicted States of Health of Electrical Energy Stores for a Device Using Machine Learning Methods

(71) Applicant: Robert Bosch GmbH, Stuttgart (DE)

(72) Inventors: Maksim V. Subbotin, San Carlos, CA (US); Christian Simonis, Leonberg (DE); Reinhardt Klein, Mountain View, CA (US)

(21) Appl. No.: 17/485,787

(22) Filed: Sep. 27, 2021

(30) Foreign Application Priority Data
Sep. 29, 2020 (DE) 10 2020 212 299.7

(51) Int. Cl. G01R 31/367; G01R 31/392

(52) U.S. Cl. CPC G01R 31/367; G06N 3/08; G01R 31/392

(57) ABSTRACT

A computer-implemented method for predicting a modeled state of health of an electrical energy store having at least one electrochemical unit, in particular a battery cell, or by according to rule-based and/or data-based mapping even in an entire system. The method including providing a data-based state of health model trained to assign a modeled state of health to the electrical energy store based on characteristics of operating variables of the electrical energy store; generating a characteristic of at least one load variable based on a provided usage pattern using a usage model; generating the characteristics of operating variables based on the at least one load variable using a predefined dynamic model; and determining a predicted modeled state of health based on the generated characteristics of operating variables.

This application claims priority under 35 U.S.C. § 119 to patent application no. DE 10 2020 212 299.7, filed on Sep. 29, 2020 in Germany, the disclosure of which is incorporated herein by reference in its entirety.

### FIELD

The disclosure relates to electrical devices operated independently of the mains and having electrical energy stores, in particular electrically driveable motor vehicles, in particular electric vehicles or hybrid vehicles, and additionally to measures for determining a state of health (SOH) of the electrical energy stores. Additionally, the disclosure relates to not only mobile but also stationary electrical energy stores.

### BACKGROUND

The supply of power to electrical devices and machines operated independently of the mains, such as e.g. electrically driveable motor vehicles, is provided using electrical energy stores, normally device batteries or vehicle batteries. These deliver electrical energy for operating the devices. Fuel cells are also possible electrical energy stores, however.

The state of health of an energy store declines appreciably over the course of its life, the effect of which is a declining maximum storage capacity. The extent of the aging of the energy store is dependent on an individual load on the energy store, i.e. in the case of vehicle batteries of motor vehicles on the usage behavior of a driver, external ambient conditions and on the vehicle battery type.

Although a physical state of health model can be used to determine the present state of health of the energy store based on historical operating state characteristics, this model is inaccurate in certain situations. This inaccuracy of the conventional state of health model hampers prediction of the state of health characteristic. However, the prediction of the characteristic of the state of health of the energy stores is an important technical variable, since it allows a financial assessment of a residual value of the energy store.

### SUMMARY

The disclosure provides for a method for predicting a state of health of an electrical energy store and an apparatus in an electrically operable device according to the coordinate claim.

According to a first aspect, there is provision for a computer-implemented method for predicting a modeled state of health of an electrical energy store having at least one electrochemical unit, in particular a battery cell, or by means of rule-based and/or data-based mapping even in an entire system, having the following steps:

providing a data-based state of health model trained to assign a state of health on the basis of characteristics of operating variables of the energy store,
generating a characteristic of at least one load variable on the basis of a provided usage pattern using a usage model;
generating the characteristics of operating variables on the basis of the at least one load variable using a predefined dynamic model;
determining a characteristic of a predicted state of health on the basis of the characteristics of operating variables.

The state of health of a rechargeable electrical energy store, in particular a device battery, is usually not measured directly. This would require a series of sensors in proximity to the energy store, which would render the manufacture of such an energy store expensive and complex and would increase the space requirement. Moreover, measurement methods for determining state of health in the devices that are suitable for everyday use are not yet available on the market. The present state of health is therefore normally ascertained using a physical health model in the devices. This physical state of health model is inaccurate in certain situations and usually exhibits model errors of up to more than 5%.

The inaccuracy of the physical health model also means that it can only indicate the present state of health of the energy store. A prediction of the state of health, which is in particular dependent on the manner of operation of the energy store, such as e.g. on the level and amount of charge flowing into and out of a device battery, and hence on a usage behavior and on usage parameters, would lead to very inaccurate predictions and is currently not envisaged.

State of health (SOH) is the key variable for device batteries as an electrical energy store for indicating a remaining battery capacity or remaining battery charge. The state of health describes an extent of the aging of the electrical energy store. In the case of a device battery or a battery module or a battery cell, the state of health can be indicated as a capacity retention rate (SOH-C) or as a rise in the internal resistance (SOH-R). The capacity retention rate SOH-C is indicated as a ratio of the measured present capacity to an initial capacity of the fully charged battery. The relative change in the internal resistance SOH-R rises as the battery ages.

There is great promise in approaches to providing for user- and usage-individual prediction of a state of health of the electrical energy store based on a data-based state of health model. The data-based state of health model can e.g. be implemented in a central processing unit (cloud) and trained using operating variables of a multiplicity of devices communicatively connected to the central processing unit.

State of health models for ascertaining states of health for electrical energy stores can be provided in the form of a hybrid state of health model, that is to say a combination of a physical health model with a data-based model. With a hybrid model, a physical state of health can be ascertained using a physical or electrochemical health model and can have a correction value applied to it that is obtained from a data-based correction model, in particular by addition or multiplication. The physical health model is based on electrochemical model equations that characterizes electrochemical states and maps them to a physical state of health, both SOH-C and SOH-R, for output.

Additionally, the correction model for the hybrid data-based state of health model can be produced using a probabilistic or artificial-intelligence-based regression model, in particular a Gaussian process model, and can be trained to correct the physical state of health. In this regard, there is therefore one data-based correction model for the state of health for correcting the SOH-C and/or another for correcting the SOH-R. Possible alternatives to supervised learning are a random forest model, an AdaBoost model, a support vector machine or a Bayesian neural network.

A prediction of the state of health is useful if a remaining life left for the energy store is supposed to be ascertained. This can involve continually querying the data-based state of health model in conjunction with predefined usage patterns of a user of the device having the electrical energy store. This requires ongoing generation of characteristics of artificial operating variables, which is needed by the physical health model. To this end, the operating variables are generated based on load variables.

This prediction option advantageously uses the trained state of health model and usage patterns, which means that more accurate prediction of the state of health is possible than with straight extrapolating methods.

The load variables are generated in a usage model. The usage model is designed to continually output characteristics of at least one load variable on the basis of usage parameters of the usage pattern. This allows a usage behavior parameterized by the usage pattern to be converted into time series of the at least one load variable. The usage pattern can therefore indicate types of load on the energy store using the load variable. The load variable indicates at least one current load for a battery as energy store. Further load variables for a battery as energy store can indicate the temperature load, the temporal frequency of the load and/or periodic loads (periodicity).

There can be provision for the usage patterns, in particular from time series of the at least one load variable, to be produced on the basis of data-based usage pattern models using historic usage behaviors, wherein the usage patterns produced are predicted in particular in order to predict the state of health.

Further, there can be provision for a dynamic model, a so-called performance model, that is advantageously in the form of an equivalent circuit model of the energy store, in the form of an electrochemical model or in the form of a single particle model. In particular, the dynamic model can indicate a response to the at least one load variable, and in particular take account of a temperature dependencies and/or a non-linearity in the dynamic response characteristic. The dynamic model generates one or more operating variables, comprising a voltage, on the basis of the at least one load variable. For an energy store having a battery cell, the current is provided on the input side of the dynamic model. The output of the dynamic model is the voltage response of the battery cell. This is dependent on temperature, inter alia, and can also take account of non-linear effects in the response characteristic.

Data-based models generally require a training process, for which training datasets are needed. The training datasets can be provided by evaluating one or a multiplicity of devices and/or trials carriers (laboratory cells). The training datasets each assign a state of health to characteristics of operating variables. Said state of health can be determined using known methods, e.g. by means of diagnostic measurements in the field, e.g. on the basis of Coulomb counting, or alternatively in the laboratory by way of reference measurements.

The data-based state of health model can be trained based on training datasets, wherein the training datasets are divided into a training set and an extended training set, wherein the health model is parameterized with the training set, and wherein the correction model is trained based on the entire extended training set, wherein the data-based state of health model is tested based on the test set, which is unknown to the model, in order to determine a validity of the data-based state of health model.

There can be provision for the electrical energy store to be operated on the basis of the characteristic of the predicted state of health, wherein in particular a remaining life of the electrical energy store is signaled on the basis of the characteristic of the predicted state of health.

According to further embodiments, the energy store can be used to operate a device, such as a motor vehicle, a pedelec, an aircraft, in particular a drone, a machine tool, a consumer electronics device, such as a mobile phone, an autonomous robot and/or a domestic appliance.

According to a further aspect, there is provision for an apparatus for predicting a state of health of an electrical energy store having at least one electrochemical unit, or by means of rule-based and/or data-based mapping even in an entire system, wherein the apparatus is designed to:

provide a data-based state of health model trained to assign a state of health to the electrochemical energy store on the basis of characteristics of operating variables of the energy store, generate a characteristic of at least one load variable on the basis of a provided usage pattern using a usage model;
generate the characteristics of operating variables on the basis of the at least one load variable using a predefined dynamic model;
determine a predicted state of health on the basis of the characteristics of operating variables.

### BRIEF DESCRIPTION OF THE DRAWINGS

Embodiments are explained in more detail below with reference to the appended drawings, in which:

FIG. 1 shows a schematic depiction of a system for providing driver- and vehicle-individual operating variables for determining a state of health of a vehicle battery in a central processing unit;

FIG. 2 shows a schematic depiction of a functional design for a hybrid state of health model;

FIG. 3 shows a flowchart to illustrate a method for training a data-based state of health model; and

FIG. 4 shows a schematic depiction of a functional design for a hybrid state of health model with usage-dependent prediction of the state of health.

### DETAILED DESCRIPTION

The method according to the disclosure is described below on the basis of vehicle batteries as an electrical energy store in a multiplicity of motor vehicles as similar devices. A data-based state of health model for the respective vehicle battery can be implemented in a control unit in the motor vehicles. The state of health model can be continually updated or retrained in a central processing unit based on operating variables of the vehicle batteries from the vehicle fleet. The state of health model is operated in the central processing unit and used to calculate aging and predict aging.

The example above is representative of a multiplicity of stationary or mobile devices with mains-independent supply of power, such as for example vehicles (electric vehicles, pedelecs, etc.), installations, machine tools, domestic appliances, TOT devices and the like, that are connected to a central processing unit (cloud) by way of an appropriate communication connection (e.g LAN, Internet).

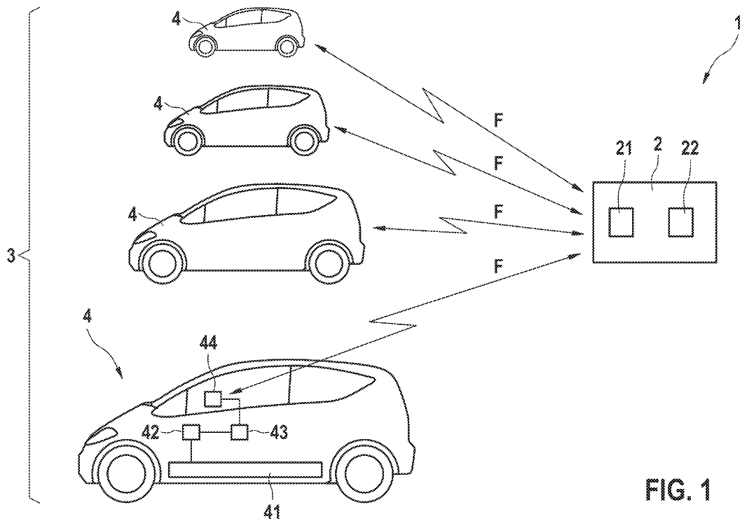

FIG. 1 shows a system 1 for collecting fleet data in a central processing unit 2 for the purpose of producing and operating and also evaluating a state of health model. The state of health model is used to determine a state of health of an electrical energy store, such as e.g. a vehicle battery or a fuel cell in a motor vehicle. FIG. 1 shows a vehicle fleet 3 with multiple motor vehicles 4.

One of the motor vehicles 4 is shown in more detail in FIG. 1. The motor vehicles 4 each have a vehicle battery 41 as a rechargeable electrical energy store, an electrical drive motor 42 and a control unit 43. The control unit 43 is connected to a communication module 44 that is suitable for transferring data between the respective motor vehicle 4 and a central processing unit 2 (a so-called cloud).

The motor vehicles 4 transmit the operating variables F, which at least indicate variables that influence the state of health of the vehicle battery, to the central processing unit 2. In the case of a vehicle battery, the operating variables F can indicate a present battery current, a present battery voltage, a present battery temperature and a present state of charge (SOC), at pack, module and/or cell level alike. The operating variables F are captured in a fast time frame of between 2 Hz and 100 Hz and can be transferred to the central processing unit 2 in uncompressed and/or compressed form on a regular basis. By way of example, the time series can be transferred to the central processing unit 2 in blocks at intervals of between 10 min and several hours.

Operating features M that relate to an evaluation period can be generated from the operating variables F in the central processing unit 2, or in other embodiments also in the respective motor vehicles 4 already. The evaluation period for determining the state of health can be between a few hours (e.g. 6 hours) and several weeks (e.g. one month). A customary value for the evaluation period is one week.

The operating features can for example comprise features referenced to the evaluation period and/or accumulated features and/or statistical variables ascertained over the entire life hitherto. In particular, the operating features can for example comprise: electrochemical states (layer thicknesses, concentrations, cyclizable lithium, etc.), histogram data for the state of charge characteristic, the temperature, the battery voltage, the battery current, in particular multidimensional histogram data regarding the battery temperature distribution over the state of charge, the charging current distribution over the temperature and/or the discharge current distribution over the temperature, accumulated total charge (Ah), an average capacity increase during a charging process (in particular for charging processes in which the charge increase is above a threshold proportion (e.g. 20%) of the total battery capacity), a maximum for the differential capacity during a measured charging process with a sufficiently large swing in the state of charge (dQ/dU: change of charge divided by change of battery voltage), and more.

The operating features M and the operating variables F reveal further details: a temporal load pattern such as charging and driving cycles, determined by usage patterns N (such as for example fast charging at high current levels or sharp acceleration or regenerative braking processes), a usage period for the vehicle battery, a charge accumulated over the operating time and a discharge accumulated over the operating time, a maximum charging current, a maximum discharge current, a frequency of charging, an average charging current, an average discharge current, a power throughput during charging and discharge, an (in particular average) charging temperature, an (in particular average) spread of the state of charge, and the like. This temporal load pattern characterizes typical usage behavior over time and can be used for prediction.

State of health (SOH) is the key variable for indicating a remaining battery capacity or remaining battery charge. The state of health describes an extent of the aging of the vehicle battery or a battery module or a battery cell and can be indicated as a capacity retention rate (SOH-C) or as a rise in the internal resistance (SOH-R). The capacity retention rate SOH-C is indicated as a ratio of the measured present capacity to an initial capacity of the fully charged battery. The relative change in the internal resistance SOH-R rises as the battery ages.

The central processing unit 2 has a state of health model implemented in it, which is in particular entirely or partly data-based. The state of health model can be used on a regular basis, i.e. e.g. after the respective evaluation period has elapsed, to ascertain the present state of health of the vehicle battery 41 based on the operating features and/or the operating variables. In other words, it is possible to ascertain a state of health of the relevant vehicle battery 41 or of this energy store associated modules or cells based on the operating variables and/or the operating features obtained from the operating variable characteristics of one of the motor vehicles 4 of the fleet 3.

Additionally, it is possible to ascertain operating variables, for example by linear or non-linear extrapolation or using a prediction model, future states of health of the vehicle battery 41. Preferably, data-based algorithms can be used to predict the operating features, e.g. autoregressive methods using ARIMA models, which characterizes not only trends but also periodicities in the characteristic of the historic operating features for the prediction thereof.

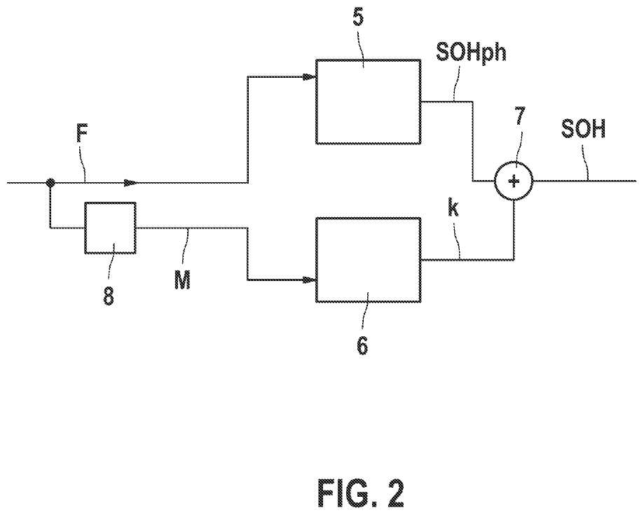

FIG. 2 schematically shows, by way of illustration, the functional design of an embodiment of a data-based state of health model 9, which is designed in a hybrid manner. The state of health model 9 comprises a physical health model 5 and a correction model 6. These receive operating variables F or operating features M from a present evaluation period. The operating features M from the present evaluation period are generated in a feature extraction block 8 based on the time series of the operating variables F.

The operating variables F go directly into the physical state of health model 5, which is preferably embodied as an electrochemical model and describes applicable electrochemical states, such as layer thicknesses (e.g. SEI thickness), change in the cyclizable lithium on the basis of anode/cathode secondary reactions, fast consumption of electrolytes, slow consumption of electrolytes, loss of the active material in the anode, loss of the active material in the cathode, etc.), using non-linear differential equations.

The physical health model 5 corresponds to an electrochemical model of the battery cell and the cell chemistry. This model ascertains internal physical battery states on the basis of the operating variables F in order to a physically based state of health SOHph having the dimension of at least one in the form of the aforementioned electrochemical states, which are linearly or non-linearly mapped to a capacity retention rate (SOH-C) and/or an internal resistance rate of rise (SOH-R) in order to provide them (SOH-C and SOH-R).

The model values for the physical state of health SOHph that are provided by the electrochemical model are inaccurate in certain situations, however, and there is therefore provision for them to be corrected with a correction variable k. The correction variable k is provided by the data-based correction model 6, which is trained using training datasets from the vehicles 4 of the vehicle fleet 3 and/or using laboratory data.

In order to determine a corrected state of health SOH that can be output, the outputs SOHph, k of the physical health model 5 and of the correction model 6, which is preferably embodied as a Gaussian process model, are applied to one another. In particular, they can be added or multiplied (not shown) in a summing block 7 in order to obtain the modeled state of health SOH for a present evaluation period, which modeled state of health can be output. In the case of addition, the confidence in the Gaussian process can continue to be used as the confidence in the corrected health value SOH of the hybrid model, which corrected health value can be output.

If there is not an adequate data basis close to the present operating feature point during the calculation of the state of health, the Gaussian process of the correction model 6 reverts to its prior, and the confidence interval, and hence the uncertainty of the prediction, becomes very large. The prior is 0 or close to 0, because the Gaussian process was trained to the residual of the purely physical health model [which usually has a normal distribution around 0] in order to correct said health model. If the Gaussian process knows a few known training data points close to the present operating feature point, which have been incorporated into the Gaussian process and hence into the hybrid state of health model by way of the training process, the Gaussian process can correct the state of health with pinpoint accuracy. This makes the uncertainty and hence the confidence interval small or narrow, since the data-driven correction, and therefore in total the state of health model, is very certain on account of the good data situation.

Other configurations of the data-based state of health model are likewise possible, for example the data-based state of health model can be in the form of a non-hybrid, purely data-based model based on a probabilistic or an artificial-intelligence-based regression model, in particular a Gaussian process model, or a Bayesian neural network. This is trained to provide a modeled state of health SOH from an operating feature point that is determined by present operating features M from a present evaluation period, the operating features M being ascertained in a feature extraction block 8 based on the time series of the operating variables F.

The operating features can be scaled and reduced in dimensions by using a PCA (principal component analysis), in order to reduce redundant linearly dependent information in the feature space as appropriate before training the correction model (unsupervised). Alternatively, a kernel PCA can also be used, so as also to be able to map non-linear effects in the complexity reduction for the data. Both before the reduction in dimensions and specifically thereafter, normalization of the entire operating feature space (or of the principal component space) takes place, e.g. with min/max scaling or the Z transformation.

The calculation of the state of health and the prediction of the state of health are therefore possible for energy stores having at least one electrochemical unit, e.g. a battery cell. The method can also be applied to the entire system of the energy store by means of rule- and/or data-based mapping. Using the example of the battery, the prediction of aging can therefore be applied not only at cell level but also directly at module level and pack level.

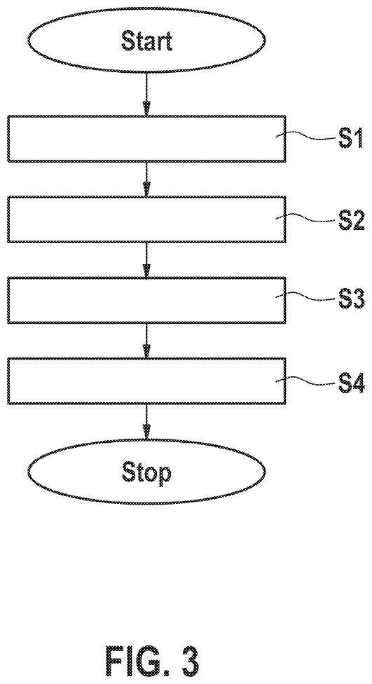

FIG. 3 shows a flowchart to illustrate a method for training the hybrid state of health model in the central processing unit 2. This is accomplished by defining training datasets that assign characteristics of operating variables to a state of health. These training datasets can be collected in the central processing unit 2 from a multiplicity of vehicles.

These training datasets are divided into a training set and a test set. The training set is used for training the hybrid state of health model, whereas the test set is used for validating the hybrid state of health model using new, unknown data.

In step S1, the physical health model 5 is parameterized on the basis of a first part of the training set, in particular by means of parameter optimization using the least squares method or the like. The physical state of health SOHph as the output from the physical health model 5 is assumed to be the state of health of the respective training dataset.

In step S2, the physical health model is applied to the entire training set of the hybrid model, i.e. a number of training datasets that at least comprises or even goes beyond the amount of training datasets that has been used to parameterize the physical health model. The error in the physical health model is accordingly evaluated in a total error for the residual as a histogram for the model error. This residual contains, in combination with the operating features M or the operating variables F, all the relevant information regarding the systematic weaknesses of the physical health model 5. The information concerning how the physical health model 5 behaves in regard to new training datasets not used for parameterizing the physical health model 5 is also obtained.

In a next step S3, the data-based correction model 6 is trained to the complete training set of the hybrid model. This training set of the hybrid model comprises at least the training set of the physical model in accordance with step S1. The correction model 6 is trained by both extracting the operating features M from the operating variables F and using the internal states of the physical health model 5 as a subset of M in order to map all operating features to an error between the model prediction (physical state of health) of the physical health model and the labelled state of health in accordance with the training dataset. This allows the correction model 6 to learn the weaknesses of the physical health model 5 so as to be able to correct the physical state of health in the correction block.

The data-based correction model 6 can be trained using cross validation and sequential bagging (bootstrap aggregating) in order to improve robustness and accuracy. If the correction model is trained, the trained hybrid state of health model can be validated using the test set in step S4, as a result of which the overall performance can be validated for the state of health calculation.

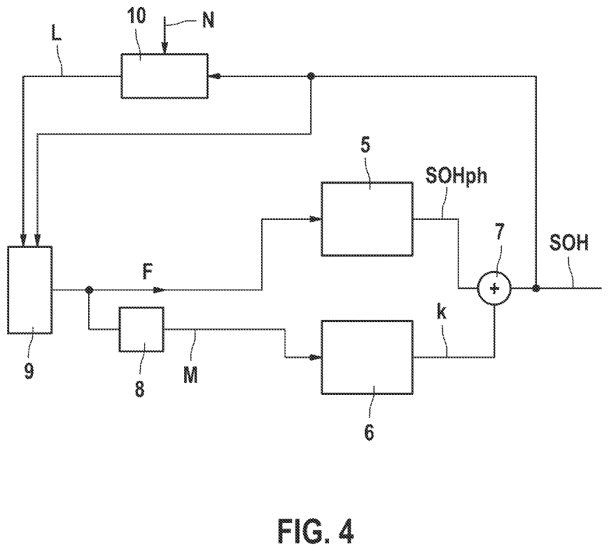

The trained hybrid state of health model can now be used to ascertain the state of health based on operating variables F. To predict a state of health on the basis of usage data, such as e.g. usage patterns N of a driver of a motor vehicle, it is possible to use a model as shown in FIG. 4. The trained hybrid model can therefore also comprise a feature extraction block and a data order reduction block (e.g. with principal component analysis: PCA), as shown in FIG. 2.

The training of the hybrid state of health model can be initiated whenever new labeled data are available, specifically whenever they contain new and relevant information. During operation in a central processing unit based on fleet data, constant retraining of the hybrid state of health model for ascertaining the state of health and for predicting the state of health is therefore possible.

FIG. 4 is based on the hybrid state of health model of FIG. 2, with a dynamic model 9 additionally being used in order to generate characteristics of battery voltages U and states of charge SOC, on the basis of the battery currents I and possibly the battery temperatures T, since the physical health model 5 requires time series or characteristics of the operating variables F. This is done on the basis of the state of health of the energy store 41 that causes the dynamic model to be updated. The response characteristic of the dynamic model 9 therefore changes on the basis of the age of the energy store 41. Preferably, this is done by updating either parameters and/or states of the dynamic model 9 on the basis of the calculated modeled state of health SOH.

In order to introduce the state of health information into the system dynamics, a usage pattern model 10 is operated on the basis of the modeled state of health SOH. It is thus possible, for example in the case of a vehicle operated using the battery, to allow for a driver being more likely to have to charge 3 times a week when the battery has aged, instead of only 2 times, as initially, in order to cover his desired distance.

The usage pattern model 10 uses predefined usage patterns N. The usage patterns are defined by usage parameters N, which are learned by the usage pattern model 10 by means of fleet data on a vehicle-individual basis, preferably using data-based methods, and are used to simulate the usage behavior of a user or a drivetrain in regard to the relevant vehicle battery 41. The usage patterns N lead to the output of a battery current I and a battery temperature T as load variables L by the usage pattern model 10, from which output the set of operating variables (F) is completed with the battery voltage U and the state of charge SOC using the dynamic model 9.

The usage patterns N can indicate types of load on the energy store, in particular periodic loads. As such, frequent fast charging by the fast charging current and a periodicity of the fast charging can be indicated. Time series are therefore obtained for the usage patterns N, specifically, for batteries, currents and temperatures, which include both weekly and seasonal periodicity effects.

The usage pattern N can also in particular indicate ambient conditions and a periodic load characteristic. The ambient conditions can e.g. be derived from a climate table, and can indicate a characteristic of the battery temperature within a day/night rhythm, for the seasons and the like, preferably using GPS-dependent weather data from the central processing unit (cloud).

It is possible for multiple usage patterns N to be indicated, which means that the resultant profile of the battery current and the battery temperature overlap.

The usage model 10 and the dynamic model 9 are adapted by means of updated states of health SOH, preferably by updating the parameters and/or states of the respective models. The dynamic model 9 can be configured in a variety of ways, such as for example an equivalent circuit model, an electrochemical model, a single particle model of battery cells or the like.

Outputs from the dynamic model 9 are a modeled battery voltage (terminal voltage) and a state of charge SOC, each of which is influenced by the modeled state of health SOH.

The possibility of predicting the modeled state of health SOH allows a driver-individual state of health trajectory to be produced for a usage pattern N. The usage pattern N is derived from stress factors and/or can be learned in a driver-individual and data-based manner on the basis of historic fleet data. Preferably, this is accomplished by using autoregressive models or alternatively deep learning methods for pattern recognition.

What is claimed is:

1. A method for predicting a modeled state of health of an electrical energy store having at least one electrochemical unit comprising:
supplying a data-based state of health model trained to assign the modeled state of health to the electrical energy store based on characteristics of operating variables of the electrical energy store;
generating a characteristic of at least one load variable based on a usage pattern using a usage model;
generating the characteristics of operating variables based on the at least one load variable using a predefined dynamic model; and
determining the predicted modeled state of health based on the generated characteristics of operating variables.

2. The method according to claim 1, wherein:
the usage pattern indicates types of load on the electrical energy store using the at least one load variable, and
the at least one load variable includes current loads, temperature loads, a temporal frequency of the load, and/or periodic loads.

3. The method according to claim 1, wherein the usage model is configured to continually output the characteristic of at least one load variable based on usage parameters of the usage pattern.

4. The method according to claim 1, wherein:
the usage pattern, from a time series of the at least one load variable, is produced based on data-based usage pattern models using historic usage behaviors, and
the usage pattern produced is predicted in order to predict the modeled state of health.

5. The method according to claim 1, wherein the predefined dynamic model includes an equivalent circuit model of the electrical energy store including an electrochemical model and/or a single particle model.

6. The method according to claim 5, wherein the predefined dynamic model indicates a response to the at least one load variable, and takes account of a temperature dependency and/or a non-linearity in a dynamic response characteristic.

7. The method according to claim 5, wherein the predefined dynamic model is adapted based on the modeled state of health, by updating model parameters or states of the predefined dynamic model based on the modeled state of health.

8. The method according to claim 1, wherein when a battery is the electrical energy store, the at least one load variable corresponds to a current, and a temperature and the operating variables correspond to a current, a voltage, a temperature, and a state of charge.

9. The method according to claim 1, wherein:
the data-based state of health model includes a hybrid model and a physical state of health model based on electrochemical model equations and is configured to output a physical state of health, and a trainable data-based correction model including a regression model, and
the correction model is trained to correct the physical state of health and to provide the corrected physical state of health as the modeled state of health with quantified uncertainty.

10. The method according to claim 9, wherein:
the data-based state of health model is trained based on training datasets,
the training datasets are divided into a training set and an extended entire training set,
the state of health model is parameterized with the training set,
the data-based correction model is trained based on the extended entire training set, and
the data-based state of health model is tested based on the extended entire training set in order to determine a validity of the data-based state of health model.

11. The method according to claim 1, wherein:
the electrical energy store is operated based on a characteristic of the predicted modeled state of health, and
a remaining life of the electrical energy store is signaled based on the characteristic of the predicted modeled state of health.

12. The method according to claim 1, wherein the electrical energy store is used to operate a motor vehicle, a pedelec, an aircraft, a drone, a machine tool, a consumer electronics device including a mobile phone, an autonomous robot, and/or a domestic appliance.

13. The method according to claim 1, wherein a computer program product includes instructions that, when the computer program product is executed by at least one data processing device, causes said data processing device to perform the method.

14. The method according to claim 1, wherein a non-transitory machine-readable storage medium includes instructions that, when executed by at least one data processing device, causes said data processing device to perform the method.

15. An apparatus for predicting a modeled state of health of an electrical energy store having at least one electrochemical unit, comprising:
at least one data processing device configured to:
supply a data-based state of health model trained to assign the modeled state of health to the electrical energy store based on characteristics of operating variables of the electrical energy store;
generate a characteristic of at least one load variable based on a provided usage pattern using a usage model;
generate the characteristics of operating variables based on the at least one load variable using a predefined dynamic model; and
determine the predicted modeled state of health based on the generated characteristics of the operating variables.
